(19) United States
(12) Patent Application Publication
(10) Pub. No.: US 2014/0312365 A1
(43) Pub. Date: Oct. 23, 2014

(54) ALTERNATING CURRENT LIGHT-EMITTING DEVICE

(71) Applicant: USHIO DENKI KABUSHIKI KAISHA, Tokyo (JP)

(72) Inventors: Akira Ishikura, Hyogo (JP); Daisaku Yokino, Hyogo (JP)

(73) Assignee: USHIO DENKI KABUSHIKI KAISHA, Tokyo (JP)

(21) Appl. No.: 14/259,916

(22) Filed: Apr. 23, 2014

(30) Foreign Application Priority Data
Apr. 23, 2013 (JP) 2013-090519

(51) Int. Cl. H01L 25/16

(52) U.S. Cl. CPC H01L 25/167
USPC 257/88

(57) ABSTRACT

The alternating current light-emitting device includes: a light-emitting module having a substantially-transparent molded piece, three or more LEDs disposed so as to be linearly lined up on the substantially-transparent molded piece with a lead frame interposed therebetween and connected in series, and a resin member formed so as to cover each of the LEDs in a direction in which the LEDs are lined up; a main substrate including the light-emitting module disposed on a front surface thereof; and a rectifier element and a current-limiting element provided on the main substrate.

### TECHNICAL FIELD

The present invention relates to an alternating current light-emitting device which emits light when an alternating current is supplied thereto.

### BACKGROUND ART

Conventionally, a lamp having a filament, called a festoon bulb, has been known as a small linear light source used for ornamental purposes (see Japanese Application Publication No. 2007-525797 (W02005/045883)). Such a lamp having a filament consumes a large amount of power. Therefore, a light-emitting device configured by disposing a plurality of LEDs so as to be linearly lined up has been proposed in recent years (see US Patent No. 7802903).

In such a light-emitting device, however, light with high directivity is emitted independently from each of the LEDs. Thus, linear light as in the lamp having a filament cannot be emitted. Furthermore, a light-emitting device configured by including: a plurality of LEDs disposed so as to be linearly lined up on a substrate; and a fluorescent member formed so as to cover each of the LEDs in a direction in which these LEDs are lined up has been proposed as a linear light source using LEDs (see Japanese Patent Application Laid-Open No. 2012-195319).

In the above-described light-emitting devices, however, since each of the LEDs is covered by the substrate and the fluorescent member, it is difficult to release heat generated by the LED. Thus, the temperature of the LED becomes excessively high during use, thereby leading to problems such as a damage of the LED or a reduction in the luminous efficiency of the LED.

Moreover, in order for the light-emitting device to emit light with an alternating current power source, a rectifier is required. Especially when full-wave rectified current is applied to the LEDs, a complicated power-supply structure is required.

### SUMMARY OF INVENTION

The present invention has been made in view of the foregoing circumstances and has as its object the provision of an alternating current light-emitting device capable of: reliably releasing heat generated by LEDs; forming a linear light source; and emitting light with the supply of an alternating current thereto. According to the present invention, there is provided an alternating current light-emitting device including:

a light-emitting module having a substantially-transparent molded piece, three or more LEDs disposed so as to be linearly lined up on the substantially-transparent molded piece with a lead frame interposed therebetween and connected in series, and a resin member formed so as to cover each of the LEDs in a direction in which the LEDs are lined up; a main substrate including the light-emitting module disposed on a front surface thereof; and

a rectifier element and a current-limiting element provided on the main substrate.

In the alternating current light-emitting device of the present invention, the resin member may preferably be formed by incorporating a phosphor in a resin. The light-emitting module may preferably be contained in a light-transmitting protective container. Preferably, the light-emitting module may be provided two; one of the light-emitting modules may be disposed on a front surface of the main substrate; the other one of the light-emitting modules may be disposed on a back surface of the main substrate; and the rectifier element and the current-limiting element may be provided on the main substrate so as to correspond to each of the light-emitting modules. Preferably, positive half-wave rectified current of an alternating current may be applied to the light-emitting module disposed on the front surface of the main substrate and negative half-wave rectified current of an alternating current may be applied to the light-emitting module disposed on the back surface of the main substrate.

An attachment hole running through the main substrate in a thickness direction thereof may preferably be formed in each of one end and the other end of the main substrate.

According to the alternating current light-emitting device of the present invention, the LEDs may be disposed on the substantially-transparent molded piece with the lead frame interposed therebetween. Thus, heat generated by the LEDs can be reliably released by the lead frame. Furthermore, since the resin member is formed so as to cover each of the LEDs in the direction in which the LEDs are lined up, a linear light source according to the configuration of the resin member can be formed. In particular, when a resin member formed by incorporating a phosphor in a resin is used as the resin member, light from the LEDs and fluorescence from the resin member are mixed together in the resin member. As a result, a linear light source according to the configuration of the resin member can be reliably formed. Furthermore, since the rectifier element and the current-limiting element are provided on the main substrate, light emission can be achieved by supply of an alternating current. Furthermore, according to the construction in which the light-emitting module is contained in the light-transmitting protective container, it is possible to prevent or suppress deterioration of the resin member due to the surrounding environment thereof. Furthermore, according to the construction in which the light-emitting module is disposed on each of the front surface and the back surface of the main substrate, light can be emitted in all directions in a plane perpendicular to a longitudinal direction of the main substrate. Furthermore, since positive half-wave rectified current of an alternating current is applied to the light-emitting module disposed on the front surface of the main substrate and negative half-wave rectified current of an alternating current is applied to the light-emitting module disposed on the back surface of the main substrate, a need to provide a complicated power-supply structure required when applying full-wave rectified current can be eliminated.

### BRIEF DESCRIPTION OF DRAWINGS

FIG. 1 is a plan view illustrating one example of an alternating current light-emitting device of the present invention.

FIG. 2 is a sectional view of the alternating current light-emitting device taken along a line A-A illustrated in FIG. 1.

FIG. 3 is an explanatory sectional view illustrating the construction of a light-emitting module.

FIG. 4 is a circuit diagram illustrating a state of electrical connection among the light-emitting modules, rectifier elements, and current-limiting elements.

FIG. 5 is an explanatory diagram illustrating one example of an ornamental lighting device using the alternating current light-emitting devices of the present invention.

FIG. 6 is an explanatory diagram illustrating a portion of the lighting device illustrated in FIG. 5 in an enlarged manner.

### DESCRIPTION OF EMBODIMENTS

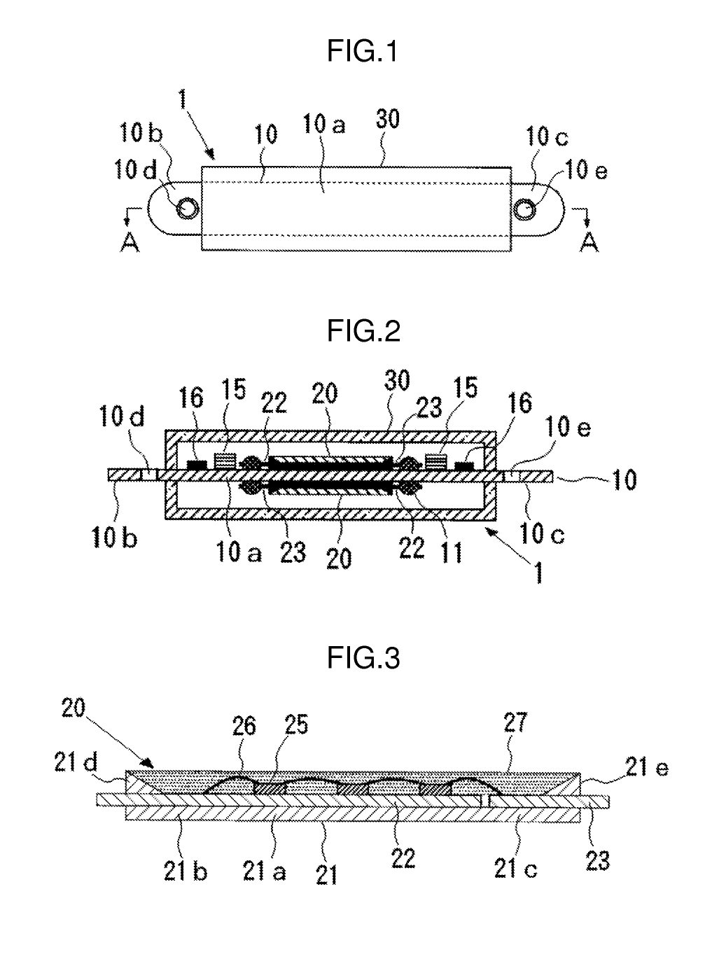

An embodiment of an alternating current light-emitting device of the present invention will be described below. FIG. 1 is a plan view illustrating one example of the alternating current light-emitting device of the present invention. FIG. 2 is a sectional view of the alternating current light-emitting device taken along a line A-A illustrated in FIG. 1. The alternating current light-emitting device 1 includes an elongated main substrate 10 formed by a printed circuit board having a wiring layer (not shown) on either side thereof. A light-emitting module 20 is disposed on each of a front surface and a back surface of a central part 10a in the main substrate 10. Rectifier elements 15 and current-limiting elements 16 are provided on the front surface of the main substrate 10 so as to correspond to the two light-emitting modules 20. Specifically, the rectifier element 15 is electrically connected to the light-emitting module 20 through the wiring layer of the main substrate 10 and the current-limiting element 16 is electrically connected to the rectifier element 15 through the wiring layer of the main substrate 10. By disposing the two rectifier elements 15 and the two current-limiting elements 16 on the front surface of the main substrate 10 in this manner, production of the alternating current light-emitting device 1 is simplified as compared to a case where the rectifier element 15 and the current-limiting element 16 are disposed on each of the front surface and the back surface of the main substrate 10. The light-emitting modules 20, the rectifier elements 15, and the current-limiting elements 16 provided two each are contained in a hollow cylindrical light-transmitting protective container 30 extending in a longitudinal direction of the main substrate 10. The main substrate 10 is disposed in such a manner that the central part 10a is positioned inside the light-transmitting protective container 30 and one end 10b and the other end 10c are protruded outwardly from both end faces of the light-transmitting protective container 30. Attachment holes 10d and 10e passing through the main substrate 10 in a thickness direction thereof are formed at the one end 10b and the other end 10c, respectively. A power-supply metal film (not shown) electrically connected to the wiring layers of the main substrate 10 is formed on an inner surface of each of these attachment holes 10d and 10e.

As examples of a material to form the main substrate 10, may be mentioned a glass fiber reinforced epoxy resin, etc. A rectifier diode may preferably be used as the rectifier element 15. A constant-current diode or a resistive element may be used as the current-limiting element 16. From the viewpoint of less heat generation, however, the constant-current diode may preferably be used. As examples of a material to form the light-transmitting protective container 30, may be mentioned light-transmitting resin materials such as an acrylic resin, a transparent ABS resin, a polycarbonate resin, and an AS resin.

FIG. 3 is an explanatory sectional view illustrating the construction of the light-emitting module 20. The light-emitting module 20 includes a rectangular dish-shaped substantially-transparent molded piece 21 having a recess on a front surface thereof. On the surface of the substantially-transparent molded piece 21, two lead frames 22 and 23, each having an elongated plate shape, are disposed so as to be spaced apart from each other and extend in a longitudinal direction of the substantially-transparent molded piece 21. To explain specifically, one lead frame 22 is disposed so as to extend in the longitudinal direction of the substantially-transparent molded piece 21 on a front surface of a central part 21a and one end 21b in the recess of the substantially-transparent molded piece 21 and penetrate through and protrude outwardly from one end wall 21d of the substantially-transparent molded piece 21. The other lead frame 23 is disposed so as to extend in the longitudinal direction of the substantially-transparent molded piece 21 on a front surface of the other end 21c in the recess of the substantially-transparent molded piece 21 and penetrate through and protrude outwardly from the other end wall 21e of the substantially-transparent molded piece 21.

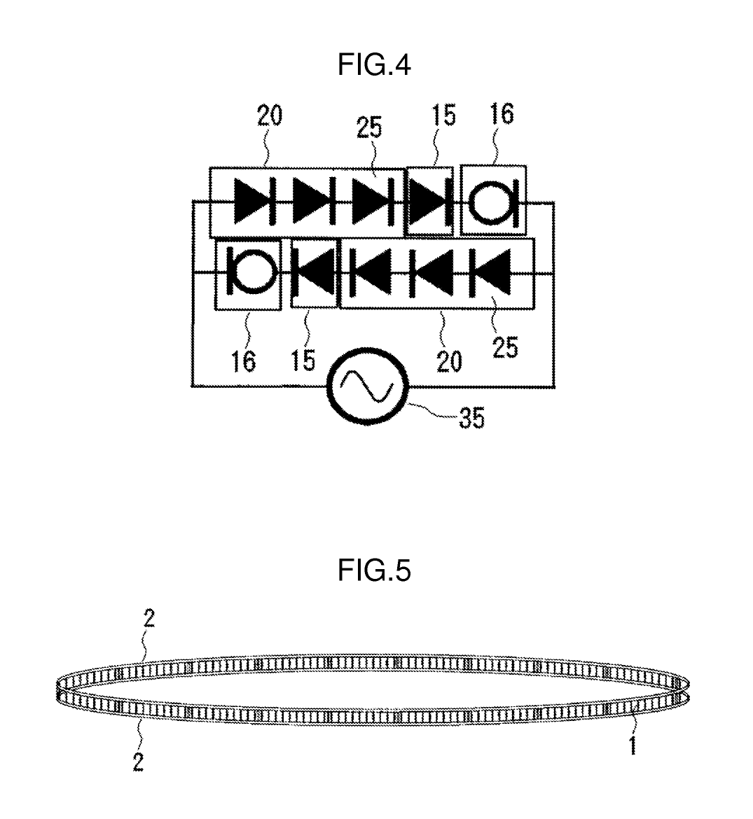

On the one lead frame 22, three or more (three in the illustrated example) LEDs 25 are disposed so as to be linearly lined up in the longitudinal direction of the substantially-transparent molded piece 21. The LEDs 25 are connected in series by a bonding wire 26. Among these LEDs 25, the LED 25 disposed closest to one end side (left side in FIG. 4) is electrically connected to the one lead frame 22 by the bonding wire 26. On the other hand, the LED 25 disposed closest to the other end side is electrically connected to the other lead frame 23 by the bonding wire 26. In the light-emitting module 20, a resin member 27 produced by incorporating a phosphor in a resin is formed so as to extend in the direction in which the LEDs 25 are lined up and cover each of the LEDs 25. In the illustrated example, the resin member 27 is formed in a state being filled in the recess of the substantially-transparent molded piece 21. The lead frames 22 and 23 in each of the light-emitting modules 20 are electrically connected to the wiring layer in the main substrate 10 by solders 11.

As examples of a material to form the substantially-transparent molded piece 21, may be mentioned synthetic resins such as nylon-based resins, epoxy-based resins, polyarylate-based resins, acrylic-based resins, polycarbonate-based resins, and olefin-based resins, glasses, etc. As examples of a material to form the lead frames 22 and 23, maybe mentioned metal materials such as copper, copper alloys, and iron. Moreover, front surfaces of the lead frames 22 and 23 maybe silver-plated. As examples of the LED 25, maybe mentioned a GaN (Gallium Nitride)-based element, an AlGaInP (Aluminum Gallium Indium Phosphide)-based element, etc. As examples of a resin to form the resin member 27, may be mentioned transparent resins having heat resistance such as silicone resins. As examples of a phosphor incorporated in the resin to form the resin member 27, may be mentioned a YAG (Yttrium Aluminum Garnet)-based phosphor, a TAG (Terbium Aluminum Garnet)-based phosphor, a sialon-based phosphor, a silicate-based phosphor, a nitride-based phosphor, a CASN-based phosphor, etc.

FIG. 4 is a circuit diagram illustrating a state of electrical connection among the light-emitting modules 20, the rectifier elements 15, and the current-limiting elements 16. As illustrated in FIG. 4, an anode terminal of the rectifier diode forming the rectifier element 15 is electrically connected to a cathode terminal of the LED 25 on one end side in the light-emitting module 20. An anode terminal of the constant-current diode forming the current-limiting element 16 is electrically connected to a cathode terminal of the rectifier diode forming this rectifier element 15. Electrically connected to an anode terminal of the LED 25 on the other end side in the one light-emitting module 20 (the upper light-emitting module 20 in FIG. 4) is a cathode terminal of the constant-current diode forming the current-limiting element 16 in the other light-emitting module 20. Electrically connected to an anode terminal of the LED 25 on the other end side in the other light-emitting module 20 is a cathode terminal of the constant-current diode forming the current-limiting element 16 in the one light-emitting module 20. A closed loop is thereby formed in which the two light-emitting modules 20 are connected in series via the rectifier elements 15 and the current-limiting elements 16.

Positive half-wave rectified current of an alternating current is applied to the one light-emitting module 20 disposed on the front surface of the main substrate 10 from an alternating current power source 35, for example. Also, negative half-wave rectified current of an alternating current is applied to the other light-emitting module 20 disposed on the back surface of the main substrate 10 from the alternating current power source 35.

One example of a concrete specification of such an alternating current light-emitting device 1 is as follows. The main substrate 10 is formed by a double-sided printed circuit board made of a glass fiber reinforced epoxy resin. The main substrate 10 has a length of 39.5 mm, a width of 5 mm, and a thickness of 1 mm. The substantially-transparent molded piece 21 in the light-emitting module 20 is made of a polyarylate-based resin. The substantially-transparent molded piece 21 has a length of 11 mm, a width of 1.2 mm, and a thickness of 0.4 mm. The lead frames 22 and 23 in the light-emitting module 20 are each formed by silver-plating a front surface of a base made of copper. The one lead frame 22 has a length of 11 mm, a width of 0.6 mm, and a thickness of 0.2 mm. The other lead frame 23 has a length of 4.8 mm, a width of 0.6 mm, and a thickness of 0.2 mm. Each of the LEDs 25 in the light-emitting module 20 has an emission wavelength of 450 to 460 nm and an input of 3 V. Three LEDs 25 are provided for one light-emitting module 20. The LED 25 has a planar size of 0.6 mm×0.24 mm and an arrangement pitch of 2.5 mm. The resin member 27 is formed by incorporating a silicate-based phosphor in a silicone resin. The resin member 27 has an upper surface with a length thereof of 10.7 mm and a lower surface with a length thereof of 9.35 mm. Also the resin member 27 has a width of 0.7 mm and a thickness of 0.6 mm. The light-transmitting protective container 30 is a hollow cylindrical container made of a resin. The light-transmitting protective container 30 has a length of 30 mm and an outer diameter of 8 mm. It has been confirmed that linear light is emitted in all directions in a plane perpendicular to the longitudinal direction of the main substrate 10 when an alternating current of 12 V is supplied to the alternating current light-emitting device 1 of the above-described specification from the alternating current power source.

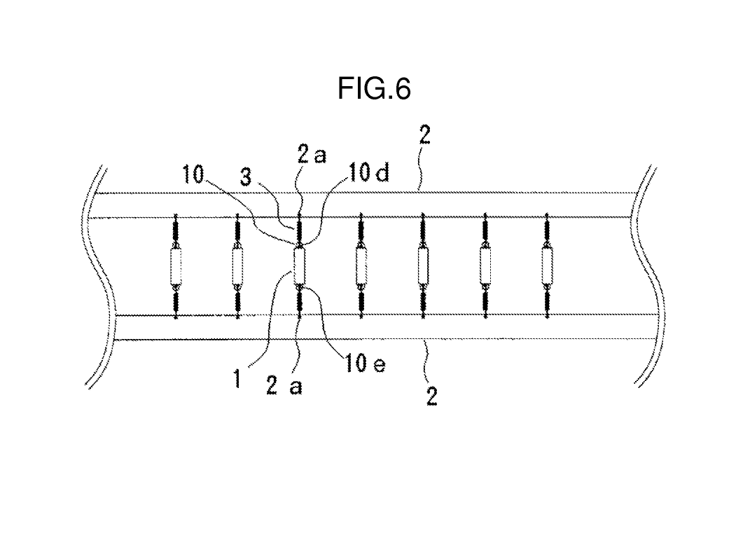

In the present invention, a large number of alternating current light-emitting devices 1 can be used to construct various ornamental lighting devices. One example of such a lighting device is as follows. FIG. 5 is an explanatory diagram illustrating one example of an ornamental lighting device using the alternating current light-emitting devices 1 of the present invention. FIG. 6 is an explanatory diagram illustrating a portion of the lighting device illustrated in FIG. 5 in an enlarged manner. In this lighting device, two frames 2, each made of a circular ring-shaped metal, are disposed so as to oppose each other with a distance therebetween. A plurality of alternating current light-emitting devices 1, each having the construction illustrated in FIG. 1, are disposed between the two frames 2 so as to be equally spaced apart from each other in a circumferential direction of the frames 2. In the frames 2, a plurality of through holes 2a are formed so as to be equally spaced apart from each other in the circumferential direction of the frames 2 corresponding to the attachment holes 10d and 10e of the main substrates 10 in the alternating current light-emitting devices 1. Support leads 3 are inserted into and fixed to the attachment holes 10d and 10e of the main substrate 10 in each of the alternating current light-emitting devices 1 and corresponding through holes 2a of the frames 2. Accordingly, the alternating current light-emitting device 1 is attached to the frames 2 with the support leads 3 interposed therebetween, and the power-supply metal films (not shown) formed on the inner surfaces of the attachment holes 10d and 10e of the main substrate 10 are electrically connected to the frames 2 with the support leads 3 interposed therebetween.

According to the above-described alternating current light-emitting device 1, the LEDs 25 are disposed on the substantially-transparent molded piece 21 with the lead frame 22 interposed therebetween. Thus, heat generated by the LEDs 25 can be released by the lead frame 22. Furthermore, since the resin member 27 is formed so as to cover each of the LEDs 25 in the direction in which the LEDs 25 are lined up, light from the LEDs 25 and fluorescence from the resin member 27 are mixed together in the resin member 27. As a result, a linear light source according to the configuration of the resin member 27 can be formed. Furthermore, since the rectifier element 15 and the current-limiting element 16 are provided on the main substrate 10 corresponding to the light-emitting module 20, light emission can be achieved by supply of an alternating current.

Furthermore, since the light-emitting module 20 is contained in the light-transmitting protective container 30, it is possible to prevent or suppress deterioration of the resin member 27 due to the surrounding environment thereof. Furthermore, since the light-emitting module 20 is disposed on each of the front surface and the back surface of the main substrate 10, light can be emitted in all directions in the plane perpendicular to the longitudinal direction of the main substrate 10. Furthermore, since positive half-wave rectified current of an alternating current is applied to the light-emitting module 20 disposed on the front surface of the main substrate 10 and negative half-wave rectified current of an alternating current is applied to the light-emitting module 20 disposed on the back surface of the main substrate 10, a need to provide a complicated power-supply structure required when applying full-wave rectified current can be eliminated.

The preceding description has been presented only to illustrate and describe exemplary embodiments of the present alternating current light-emitting device. It is not intended to be exhaustive or to limit the invention to any precise form disclosed. It will be understood by those skilled in the art that various changes may be made and equivalents may be substituted for elements thereof without departing from the scope of the invention. In addition, many modifications may be made to adapt a particular situation or material to the teachings of the invention without departing from the essential scope. Therefore, it is intended that the invention not be limited to the particular embodiment disclosed as the best mode contemplated for carrying out this invention, but that the invention will include all embodiments falling within the scope of the claims. The invention may be practiced otherwise than is specifically explained and illustrated without departing from its spirit or scope.

What is claimed is:

1. An alternating current light-emitting device comprising:
a light-emitting module comprising a substantially-transparent molded piece, three or more LEDs disposed that are linearly lined up on the substantially-transparent molded piece with a lead frame interposed therebetween and connected in series, and a resin member formed that covers each of the LEDs in a direction in which the LEDs are lined up;
a main substrate including the light-emitting module disposed on a front surface of the main substrate; and
a rectifier element and a current-limiting element provided on the main substrate.

2. The alternating current light-emitting device according to claim 1, wherein the resin member is formed by incorporating a phosphor in a resin.

3. The alternating current light-emitting device according to claim 1, wherein the light-emitting module is contained in a light-transmitting protective container.

4. The alternating current light-emitting device according to claim 1, wherein
the alternating current light emitting deice comprises first and second light-emitting modules;
the first light-emitting module is disposed on a front surface of the main substrate;
the second two light-emitting module is disposed on a back surface of the main substrate; and
the rectifier element and the current-limiting element are provided on the main substrate so as to correspond to each of the first and second light-emitting modules.

5. The alternating current light-emitting device according to claim 4, wherein a positive half-wave rectified current of an alternating current is applied to the first light-emitting module and a negative half-wave rectified current of an alternating current is applied to the second light-emitting module.

6. The alternating current light-emitting device according to claim 1, wherein an attachment hole running through the main substrate in a thickness direction is formed in each of one end and the other end of the main substrate.
